(19) United States
(12) Patent Application Publication
(10) Pub. No.: US 2017/0025603 A1
(43) Pub. Date: Jan. 26, 2017

(54) SEMICONDUCTOR DEVICE PRODUCTION METHOD AND PRODUCTION APPARATUS

(71) Applicant: TOKYO ELECTRON LIMITED, Tokyo (JP)

(72) Inventor: Kenichi HARA, Nirasaki-shi (JP)

(21) Appl. No.: 15/124,395

(22) PCT Filed: Feb. 23, 2015
(86) PCT No.: PCT/JP2015/056011

§ 371 Date: Sep. 8, 2016

(30) Foreign Application Priority Data
Mar. 12, 2014 (JP) 2014-049305

(51) Int. Cl. H01L 43/12; H01L 43/02; H01J 37/32; G11C 11/16; H01L 43/10; H01L 43/08; H01L 21/67

(52) U.S. Cl. CPC H01L 43/12; H01L 43/08; H01L 43/02; H01L 21/67069; G11C 11/161; H01L 43/10; H01J 37/32009; H01J 37/3244; H01J 2237/334

(57) ABSTRACT

A method for producing a semiconductor device capable of showing its desired performance. In an etching module of a semiconductor device production apparatus, a plasma etching is performed for a stack structure of a wafer such that a portion not covered by a hard mask in the stack structure is etched away. The wafer having a pillar structure whose lateral side is inclined by the plasma etching is loaded into a trimming module. An acetic acid gas is supplied into a processing chamber of the trimming module. In addition, an oxygen GCIB is irradiated from a GCIB irradiating device toward the pillar structure.

### TECHNICAL FIELD

The present disclosure relates to a method and apparatus for producing a semiconductor device a stack structure including an MTJ element.

### BACKGROUND

In recent years, MRAMs (Magneto-resistive Random Access Memories) have been developed as the next generation nonvolatile memories alternative to DRAMs and SRAMs. The MRAM includes an MTJ (Magnetic Tunnel Junction) element instead of a capacitor and stores information using a magnetization state of the MTJ element.

The MTJ element is composed of an insulating film, for example, an MgO film, and two ferromagnetic films, for example, CoFeB films, which face each other via the insulating film. The MRAM is composed of the MTJ element and a noble metal film such as a Ta film or a Ru film.

As shown in FIG. 134, in a stack structure including an MgO film 150, two CoFeB films 151 and 152 formed to face each other via the MgO film 150, a Ta film 153 and a Ru film 154, the respective films are etched using an insulating hard mask 155 or a metal hard mask 156 so that a pillar structure (columnar structure) 157 is obtained as shown in FIG. 13B. Thus, an MRAM is manufactured.

Since a noble metal film such as the Ta film 153 or the Ru film 154 is generally hard to etch, the noble metal film is etched by a physical etching of a sputtering mode in the above-mentioned stack structure. At this time, as an etching means, an ion milling (see, e.g., Patent Document 1) or a plasma etching is used.

### PRIOR ART DOCUMENTS

### Patent Documents

Patent Document 1: Japanese laid-open publication No. 2005-243420

However, for the ion milling, a damage layer whose crystallinity is lost may be formed in a lateral side of the pillar structure 157 by implantation of ions. In addition, for the plasma etching, if a sputtering is strong, the lateral side of the pillar structure 157 is inclined, and if the sputtering is weak, a polymer layer produced by a combination of carbons and hydrogens in material of the respective films or process gases is formed on the lateral side of the pillar structure 157.

The damage layer, the inclination of the lateral side and the polymer layer hamper an insulation property of the MgO film and magnetic properties of the CoFeB films. As such, when the pillar structure 157 is formed by only the ion milling or the plasma etching, the MRAM having the pillar structure 157 may not show its desired performance.

### SUMMARY

Some embodiments of the present disclosure provide a method and apparatus for producing a semiconductor device which is capable of showing its desired performance.

According to one embodiment of the present disclosure, there is provided a method for producing a semiconductor device including at least a MTJ element and a metal layer, the MTJ element having a stack structure composed of a first ferromagnetic film, an insulating film and a second ferromagnetic film which are stacked in this order, including: a first processing step of etching the stack structure by an ion milling or a plasma etching: and a second processing step of irradiating a gas cluster ion beam (GCIB) onto the stack structure after the first processing step, wherein the second processing step includes supplying an acetic acid gas around the stack structure and irradiating an oxygen GCIB onto the stack structure.

According to another embodiment of the present disclosure, there is provided an apparatus for producing a semiconductor device having a stack structure including at least a MTJ element and a metal layer, including: a first processing unit configured to etch the stack structure by an ion milling or a plasma etching; and a second processing unit configured to irradiate a gas cluster ion beam (GCIB) onto the etched stack structure, wherein the second processing unit supplies an acetic acid gas around the stack structure and irradiates an oxygen GCIB onto the stack structure.

According to the present disclosure, an oxygen GCIB is irradiated onto a damage layer of the stack structure produced in the first processing step, an inclination of a lateral side of the stack structure or a polymer layer formed on the lateral side of the stack structure, under an atmosphere of an acetic acid gas. Metal including a noble metal as a hard-to-etch material is presented in the damage layer, the inclination of the lateral side of the stack structure or the polymer layer. The damage layer, the inclination of the lateral side of the stack structure or the polymer layer are chemically removed by promotion of oxidation of the metal by kinetic energy of oxygen gas clusters and oxygen molecules decomposed from the oxygen gas clusters, and surrounding and sublimation of a metal oxide by acetic acid molecules. As a result, since an insulation property of an MgO film and a magnetic properties of CoFeB films in an MTJ element are not hampered, a semiconductor device including the MTJ element can show its desired performance.

### BRIEF DESCRIPTION OF THE DRAWINGS

FIG. 1 is a plan view schematically illustrating a configuration of a semiconductor device production apparatus according to a first embodiment of the present disclosure.

FIG. 2 is a sectional view schematically illustrating a configuration of a trimming module shown in FIG. 1.

FIG. 3 is a sectional view schematically illustrating a configuration of a GCIB irradiating device shown in FIG. 2.

FIGS. 4A to 4C are views for explaining a process in which a lateral side is inclined in a stack structure including an MTJ element.

FIGS. 5A to 5C are process views illustrating a semiconductor device production method according to a first embodiment of the present disclosure.

FIGS. 6A to 6C are views for explaining a process in which a polymer layer is formed on a lateral side of a stack structure including an MTJ element.

FIGS. 7A to 7C are process views illustrating a semiconductor device production method according to a second embodiment of the present disclosure.

FIGS. 8A to 8C are views for explaining a process in which a damage layer is formed on a lateral side of a stack structure including an MTJ element.

FIGS. 9A to 9C are process views illustrating a semiconductor device production method according to a third embodiment of the present disclosure.

FIG. 10 is a sectional view schematically illustrating a configuration of an MTJ element formed in a stepped shape.

FIG. 11 is a graph illustrating etched amounts of an MgO film and a CoFeB film when irradiating an oxygen GCIB.

FIGS. 12A to 12F are process views illustrating a semiconductor device production method according to a fourth embodiment of the present disclosure.

FIGS. 13A and 13B are process views for explaining a procedure of producing an MRAM including an MTJ element.

### DETAILED DESCRIPTION

Embodiments of the present disclosure will now be in detail described with reference to the accompanying drawings.

First, a production apparatus for performing a semiconductor device production method according to a first embodiment of the present disclosure will be described.

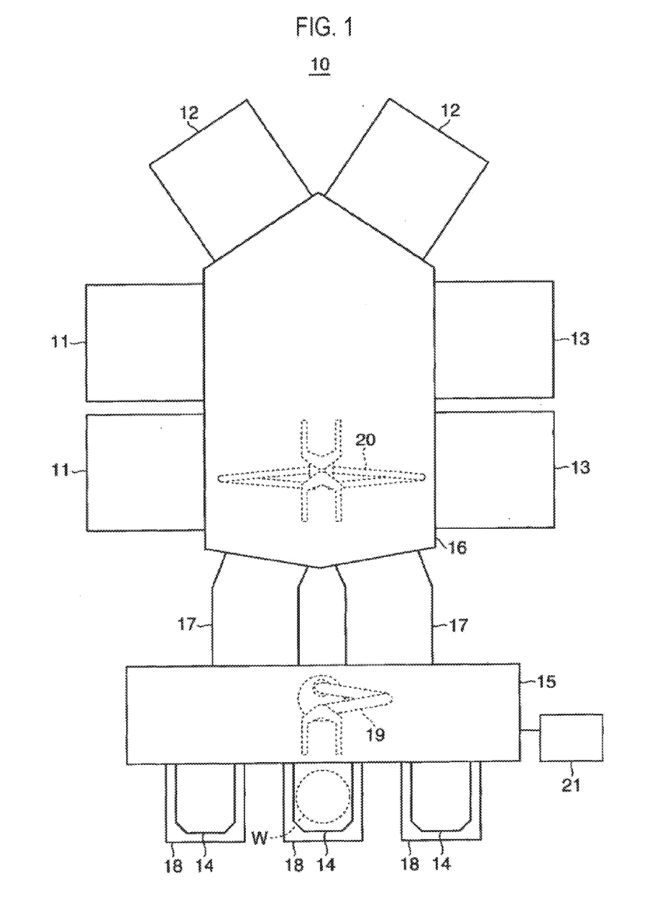

FIG. 1 is a plan view schematically illustrating a configuration of a semiconductor device production apparatus according to this embodiment.

Referring to FIG. 1, a semiconductor device production apparatus 10 includes: etching modules 11 (first processing units), each of which performs a physical etching process on a wafer W having a stack structure composed of a plurality of films formed by a film forming process; trimming modules 12 (second processing units), each of which performs a trimming process on the wafer W that has been subjected to the etching process, using a GCIB (Gas Cluster Ion Beam): film forming modules 13 (film forming units), each of which forms a nitride film such as a silicon nitride (SiN) film to cover the stack structure of the wafer W that has been subjected to the trimming process; a loader module 15 which unloads the wafer W from each of a plurality of containers such as FOUPs (Front Opening Unified Pods) 14 accommodating the plurality of wafers W (indicated by a broken line in the figure): a transfer module 16 which loads/unloads the wafer W into/from the respective etching module 11, the respective trimming module 12 and the respective film forming module 13; and two load lock modules 17 which deliver the wafers W between the loader module 15 and the transfer module 16.

The loader module 15 is configured by a substantially rectangular parallelepiped transfer chamber whose interior is exposed to the atmosphere. The loader module 15 includes load ports 18 in which the FOUPs 14 can be installed, and a transfer arm 19 (indicated by a broken line in the figure) installed inside the loader module 15 and configured to load/unload the wafers W into/from the respective FOUPs 14 installed in the load ports 18.

The transfer module 16 includes a transfer chamber whose interior is depressurized, and a transfer arm 20 (indicated by a broken line in the figure) installed inside the transfer chamber. The etching modules 11, the trimming modules 12 and the film forming modules 13 are connected to the transfer module 16 while being radially arranged around the transfer module 16. The transfer module 16 transfers the wafers W between the etching modules 11, the trimming modules 12, the film forming modules 13 and the load lock modules 17 by the transfer arm 20.

Each of the load lock modules 17 is configured by a standby chamber whose interior can be defined to an atmospheric pressure environment and a depressurized environment. The transfer arm 19 of the loader module 15 and the transfer arm 20 of the transfer module 16 transfer the wafers W through the respective load lock modules 17.

Each of the etching modules 11 includes a processing chamber whose interior is depressurized, and performs a physical etching process on the wafer W inside the processing chamber by an ion milling or a plasma etching. Each of the trimming modules 12 also includes a processing chamber whose interior is depressurized, and performs a trimming process on the wafer W inside the processing chamber by irradiating GCIB from a GCIB irradiating device 26 (to be described later) on the wafer W. Each of the film forming modules 13 also includes a processing chamber whose interior is depressurized, and forms a SiN film to cover the stack structure of the wafer W inside the processing chamber by a plasma-based CVD process.

In addition, the semiconductor device production apparatus 10 includes a control part 21. For example, the control part 21 performs a process corresponding to a desired recipe for each wafer W by controlling operations of respective components of the semiconductor device production apparatus 10 according to a program for implementing the desired recipe. Although in FIG. 1, the control part 21 has been shown to be connected to the loader module 15 and the trimming modules 12, the control part 21 may be connected to any component in the semiconductor device production apparatus 10. Further, any component may include the control part 21. Furthermore, the control part 21 may be configured as an external server which is installed in a place different from a position where the semiconductor device production apparatus 10 is installed.

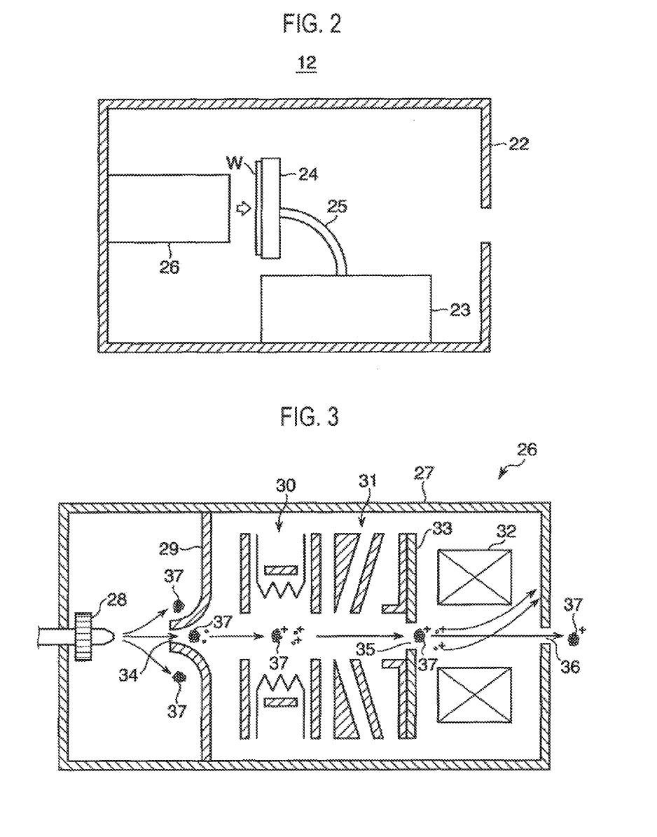

FIG. 2 is a sectional view schematically illustrating a configuration of the trimming module shown in FIG. 1.

Referring to FIG. 2, the trimming module 12 includes a processing chamber 22 in which the wafer W is accommodated, a mounting table 23 disposed in a lower portion inside the processing chamber 22, an electrostatic chuck 24 which is mounted on an upper surface of the mounting table 23 and electrostatically adsorbs the wafer W, an arm part 25 which separates the electrostatic chuck 24, along with the wafer W electrostatically adsorbed thereon, from the mounting table 23, and a GCIB irradiating device 26 which is disposed on a lateral side of the processing chamber 22 and substantially horizontally irradiates oxygen GCIBs.

In the trimming module 12, the arm part 25 separates the electrostatic chuck 24 from the mounting table 23 such that the electrostatically-adsorbed wafer W faces the GCIB irradiating device 26. An acetic acid gas is supplied into the processing chamber 22 and the GCIB irradiating device 26 irradiates the oxygen GCIB toward the wafer W positioned to face the GCIB irradiating device 26.

The electrostatic chuck 24 includes a refrigerant passage (not shown) and a heater (both not shown) buried therein, and can heat the electrostatically-adsorbed wafer W and cool down the wafer W.

FIG. 3 is a sectional view schematically illustrating a configuration of the GCIB irradiating device shown in FIG. 2.

Referring to FIG. 3, the GCIB irradiating device 26 includes a cylindrical main body 27 whose interior is depressurized and substantially horizontally disposed, a nozzle 28 disposed at one end of the main body 27, a plate-like skimmer 29, an ionizer 30, an accelerator 31, a permanent magnet 32 and an aperture plate 33.

The nozzle 28 is disposed along a central axis of the main body 27 and emits a gas such as an oxygen gas along the central axis. The skimmer 29 is disposed to cover a cross section in the main body 27. The skimmer 29 has a central portion projecting toward the nozzle 28 along the central axis of the main body 27 and a fine hole 34 formed at a position corresponding to the projected central portion. Similarly, the aperture plate 33 is disposed to cover the cross section in the main body 27 and has an aperture hole 35 formed at a portion corresponding to the central axis of the main body 27. The other end of the main body 27 also has an aperture hole 36 formed at a portion corresponding to the central axis of the main body 27.

The ionizer 30, the accelerator 31 and the permanent magnet 32 are disposed to surround the central axis of the main body 27, respectively. The ionizer 30 heats a built-in filament to emit electrons toward the central axis of the main body 27. The accelerator 31 generates a potential difference along the central axis of the main body 27. The permanent magnet 32 generates a magnetic field in the vicinity of the central axis of the main body 27. Hereinafter, a voltage to be applied to the ionizer 30 in order to heat the filament is referred to as an “ionization voltage” and a voltage to be applied to the accelerator 31 in order to generate the potential difference is referred to as an “acceleration voltage.”

In the GCIB irradiating device 26, the nozzle 28, the skimmer 29, the ionizer 30, the accelerator 31, the aperture plate 33 and the permanent magnet 32 are arranged in this order, from one end side (left side in FIG. 3) of the main body 27 to the other end side (right side in FIG. 3).

Once the nozzle 28 injects the oxygen gas toward the depressurized interior of the main body 27, a volume of the oxygen gas rapidly increases so that the oxygen gas is subjected to a rapid adiabatic expansion, thus rapidly cooling down oxygen molecules. This decreases a kinetic energy so that the oxygen molecules are in close contact with each other by virtue of an intermolecular force (Van der Waals force) exerted between the respective oxygen molecules. Thus, a plurality of oxygen gas clusters 37 which is configured by a plurality of oxygen molecules, is formed.

The skimmer 29 selects, among the plurality of oxygen gas clusters 37, one oxygen gas cluster 37 that moves along the central axis of the main body 27 using the fine hole 34. The ionizer 30 allows electrons to collide with the selected oxygen gas cluster 37 that move along the central axis of the main body 27, thereby ionizing the selected oxygen gas cluster 37. The accelerator 31 accelerates the ionized oxygen gas cluster 37 toward the other end side of the main body 27 by virtue of the potential difference. The aperture plate 33 selects, among the accelerated oxygen gas clusters 37, one oxygen gas cluster 37 that moves along the central axis of the main body 27 using the aperture hole 35. The permanent magnet 32 changes a travel path of the oxygen gas cluster 37 of a relatively small size (including monomer of the ionized oxygen molecules) by virtue of the magnetic field. In the permanent magnet 32, the oxygen gas cluster 37 of a relatively large size is also affected by the magnetic field. However, since a mass of the relatively large oxygen gas cluster 37 is large, the relatively large oxygen gas cluster 37 continues to move along the central axis of the main body 27 while maintaining the travel path thereof by virtue of a magnetic force.

The relatively large oxygen gas cluster 37, which passed through the permanent magnet 32, is discharged, as the oxygen GCIB, outside of the main body 27 through the aperture hole 36 formed at the other end side of the main body 27 such that the relatively large oxygen gas cluster 37 is irradiated toward the wafer W.

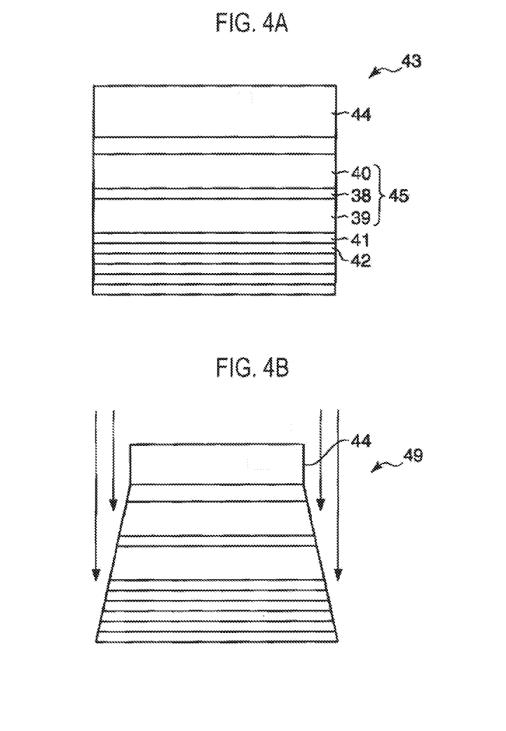

Meanwhile, as shown in FIG. 4A, a stack structure 43 including an MgO film 38 (insulating film), two CoFeB films 39 and 40 (first and second ferromagnetic films) facing each other via the MgO film 38, a Ta film 41 and a Ru film 42, which are stacked one above another, is formed on the wafer W. In the stack structure 43, the respective films are etched using a hard mask 44 formed on the stack structure 43 to obtain a pillar structure 49. Thus, an MRAM is manufactured. The MgO film 38 and the CoFeB films 39 and 40 constitute an MTJ element 45.

Specifically, first, the etching module 11 of the semiconductor device production apparatus 10 performs a plasma etching as a physical etching process on the stack structure 43 of the wafer W. At this time, if a bias voltage to be applied to the wafer W is set to be large such that a sputtering by positive ions in plasma is strong, the hard mask 44 as well as the respective films of the stack structure 43 is cut by the etching and is reduced in size over time.

In an initial stage of the plasma etching performed on the stack structure 43, since the stack structure 43 is cut from the uppermost film, an etched amount is increased as it goes to the upper film. Thus, a lateral side of the pillar structure 49 becomes inclined (FIG. 4B). Thereafter, if the hard mask 44 is reduced to decrease a width thereof, a portion of the upper film is newly exposed and further etched. When the portion of the upper film is etched to newly expose a portion of a lower film, the newly exposed portion of the lower film is also etched. In other words, since the etched amounts of all of the films become substantially the same level, the inclination of the lateral side of the pillar structure 49 is maintained (FIG. 4C).

This embodiment uses the oxygen GCIB to alleviate the inclination of the lateral side of the pillar structure 49.

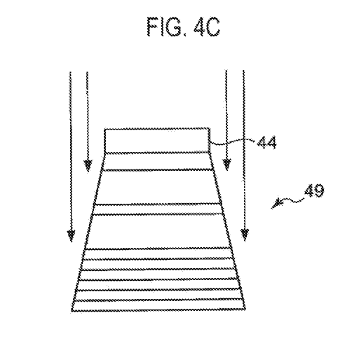

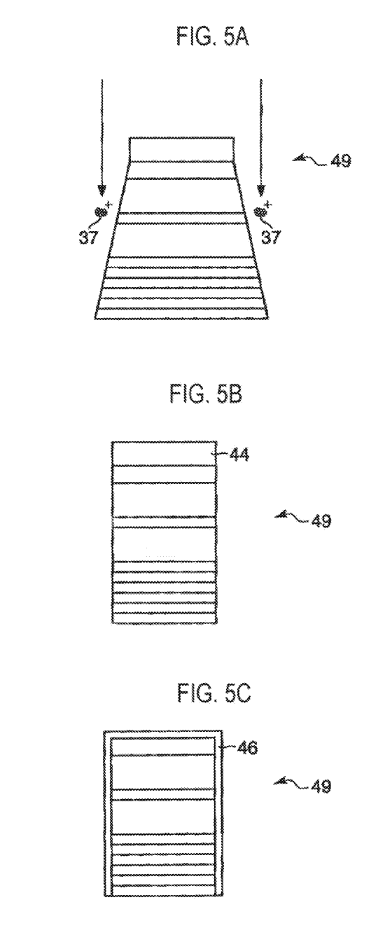

FIGS. 5A to 5C are process views illustrating a semiconductor device production method according to this embodiment.

Referring to FIGS. 5A to 5C, first, in the etching module 11, the stack structure 43 of the wafer W is subjected to the plasma etching such that a portion not covered by the hard mask 44 in the stack structure 43 of the wafer W is cut by the etching. Thus, the pillar structure 49 is obtained (in a first processing step).

Subsequently, the wafer W having the pillar structure 49 with its lateral side inclined by the plasma etching is loaded into the trimming module 12 and is disposed to face the GCIB irradiating device 26 by a combination of the mounting table 23 and the arm part 25.

Thereafter, an acetic acid gas is supplied into the processing chamber 22 of the trimming module 12. Further, an oxygen GCIB is irradiated from the GCIB irradiating device 26 toward the wafer W (FIG. 5A) (in a second processing step). In the pillar structure 49 of the wafer W to which the oxygen GCIB is irradiated, the oxygen gas clusters 37 collide with the respective films of the pillar structure 49. Oxidations of the respective films are promoted by a kinetic energy of the oxygen gas clusters 37 and oxygen molecules decomposed from the oxygen gas clusters 37, thus producing a metal oxide composing the respective films, including a noble metal such as Ta or Ru which is hard to etch. At this time, the noble metal oxide is, as it is, sublimated due to its high vapor pressure. Oxide of other metals such as Co, Fe or Ta is sublimated and removed from the respective films as the metal oxide is surrounded by a number of acetic acid molecules of the acetic acid gas.

The oxygen gas clusters 37 have very high straightness since they are accelerated along the central axis of the main body 27 by the accelerator 31 of the GCIB irradiating device 26. Accordingly, when the wafer W is located opposite the GCIB irradiating device 26 such that the top portion of the pillar structure 49 directly faces the GCIB irradiating device 26, the oxygen gas clusters 37 collide with only a portion not covered by the reduced hard mask 44 in the respective films of the pillar structure 49, that is to say, an inclined portion of the lateral side of the pillar structure 49, without colliding with a portion covered by the reduced hard mask 44. Therefore, the inclined portion is removed through the oxidation and sublimation caused by the oxygen gas clusters 37 and the acetic acid gas, thus alleviating the inclination of the lateral side of the pillar structure 49 (FIG. 5B).

Thereafter, the hard mask 44 is removed from the wafer W having the pillar structure 49 with no inclination of its lateral side, and subsequently, the wafer W is moved from the trimming module 12 into the film forming module 13 via the transfer module 16. Since the interiors of the processing chambers or transfer chambers of the trimming module 12, the transfer module 16 and the film forming module 13 are depressurized, it is possible to prevent a natural oxide film from being formed in the pillar structure 49 with end portions of the respective films exposed.

Subsequently, in the film forming module 13, a SiN film 46 is formed to cover the exposed surface of the pillar structure 49 by a plasma-based CVD process (FIG. 5C) and the method is ended.

With the semiconductor device production method of FIGS. 5A to 5C, the oxygen GCIB is irradiated onto the inclined portion of the lateral side of the pillar structure 49, which is formed by the plasma etching, under an atmosphere of the acetic acid gas. Accordingly, the inclined portion of the lateral side of the pillar structure 49 is chemically removed through the promoted oxidations of metals constituting the respective films by kinetic energy of the oxygen gas clusters 37 and oxygen molecules decomposed from the oxygen gas clusters 37 and further through the surrounding and sublimation of the metal oxide by the acetic acid molecules. As a result, since an insulation function of the MgO film 38 of the pillar structure 38 and a magnetic property of the CoFeB films 39 and 40 are not inhibited, the MRAM including the MTJ element 45 can manifest a desired performance.

In the semiconductor device production method of FIGS. 5A to 5C, the irradiated oxygen GCIB is easily decomposed and scattered as oxygen molecules when the oxygen gas clusters 37 in the oxygen GCIB collide with the inclined portion of the lateral side of the pillar structure 49. That is to say, since the oxygen gas clusters 37 are not directly implanted into the respective films of the pillar structure 49, occurrence of damage is suppressed in the respective films. However, if the kinetic energy of the oxygen gas clusters 37 is large, the kinetic energy of the decomposed oxygen molecules are also large so that the oxygen molecules may be implanted into the respective films of the pillar structure 49, which may result in occurrence of damage in the respective films. Accordingly, the acceleration voltage of the accelerator 31 of the GCIB irradiating device 26 may be set to be equal to or lower than 10 kV to prevent the kinetic energy of the oxygen gas clusters 37 from being excessively increased.

Next, a semiconductor device production method according to a second embodiment of the present disclosure will be described. The semiconductor device production method according to the second embodiment is also performed by the semiconductor device production apparatus 10.

The second embodiment is basically identical to the first embodiment in configuration and operation and is different from the first embodiment in that a bias voltage applied to the wafer W is set not to be large when the plasma etching is performed on the stack structure 43 of the wafer W. Therefore, duplicate configurations and operations will not be explained and only different configurations and operations will be explained below.

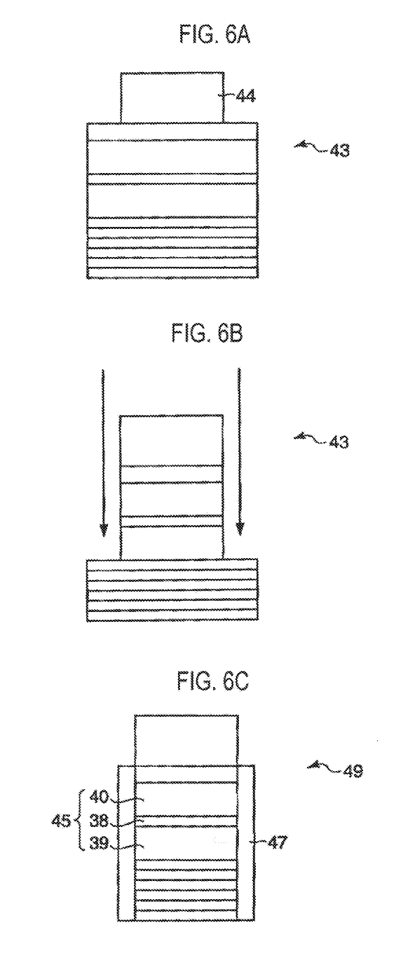

For example, in the etching module 11, as shown in FIG. 6A, when the plasma etching is performed with respect to the stack structure 43 of the wafer W on which the hard mask 44 is formed, if the bias voltage applied to the wafer W is set not to be large and a sputtering by positive ions in plasma is set to be strong, the hard mask 44 is not cut by the etching. Thus, the hard mask 44 is not reduced in size even with time.

If the size of the hard mask 44 is not reduced and the width thereof is not changed, a portion covered by the hard mask 44 in the respective films of the stack structure 43 is not cut by the etching, whereas a portion not covered by the hard mask 44 in the respective films of the stack structure 43 continues to be cut by the etching. Therefore, the lateral side of the pillar structure 49 is not inclined (FIG. 6B).

However, even if a polymer produced by coupling metals (including noble metal) of the respective films of the stack structure 43 or metals obtained by combining carbon and hydrogen in the processing gas used in the plasma etching, with an organic substance, is attached to the lateral side of the pillar structure 49, since the attached polymer cannot be removed if the sputtering is weak, a polymer layer 47 is formed on the lateral side of the pillar structure 49 (FIG. 6C). Since the polymer layer 47 may contain metal, the MgO film 38 and the CoFeB films 39 and 40 of the pillar structure 49 may be in electrical conduction, which may interfere with the normal operation of the MRAM including the MTJ element 45.

In this embodiment, the oxygen GCIB is used to remove the polymer layer 47 formed on the lateral side of the pillar structure 49.

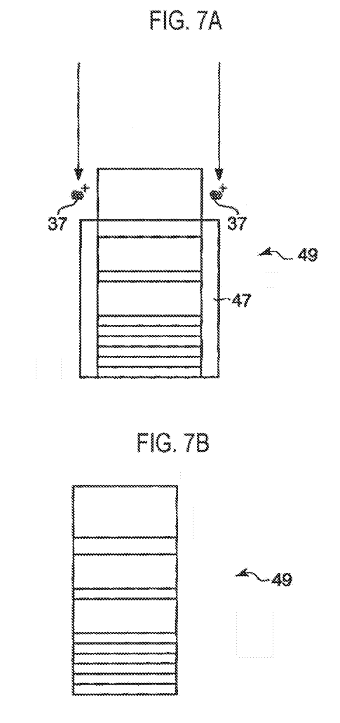

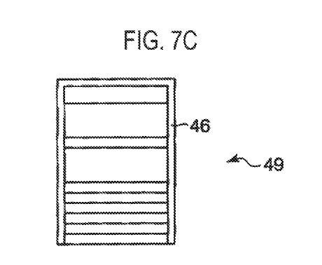

FIGS. 7A to 7C are process views illustrating the semiconductor device production method according to this embodiment.

Referring to FIGS. 7A to 7C, first, a portion not covered by the hard mask 44 in the stack structure 43 of the wafer W is etched away by performing the plasma etching on the stack structure 43 of the wafer W in the etching module 11, thereby obtaining the pillar structure 49 (in a first processing step).

Subsequently, the wafer W having the pillar structure 49 with its lateral side on which the polymer layer 47 is formed by the plasma etching is loaded into the trimming module 12 and is positioned to face the GCIB irradiating device 26 by a combination of the mounting table 23 and the arm part 25.

Thereafter, an acetic acid gas is supplied into the processing chamber 22 of the trimming module 12. Further, an oxygen GCIB is irradiated from the GCIB irradiating device 26 toward the wafer W (FIG. 7A) (in a second processing step). Since the oxygen gas clusters 37 have very high straightness, if the wafer W is positioned to face the GCIB irradiating device 26 such that the top portion of the pillar structure 49 directly faces the GCIB irradiating device 26, the oxygen gas clusters 37 collide with only the polymer layer 47 not covered by the hard mask 44.

At this time, oxidation of the metal (including the noble metal) existing in the polymer layer 47 is promoted by kinetic energy of the oxygen gas clusters 37 and oxygen molecules decomposed from the oxygen gas clusters 37, thereby producing a metal oxide. Since the noble metal oxide has a high vapor pressure, it is sublimated in-situ by heat generated in the GCIB irradiation. Oxide of other metal such as Co, Fe or Ta is surrounded by a number of acetic acid molecules of the acetic acid gas. The oxide of other metal surrounded by the number of acetic acid molecules is sublimated and removed from the polymer layer 47 by heat generated in the GCIB irradiation.

In addition, an organic substance contained in the polymer layer 47 is also decomposed by the kinetic energy of the oxygen gas clusters 37 and is removed while being sublimated as carbon dioxide (CO₂) or water (H₂O). As a result, the polymer layer 47 is removed (FIG. 7B).

Thereafter, the hard mask 44 is removed from the wafer W having the pillar structure 49 in which the polymer layer 47 is removed from the lateral side, and subsequently, the wafer W is moved from the trimming module 12 into the film forming module 13 via the transfer module 16.

Subsequently, in the film forming module 13, a SiN film 46 is formed to cover the exposed surface of the pillar structure 49 by the plasma-based CVD process (FIG. 7C), and the method is ended.

With the semiconductor device production method of FIGS. 7A to 7C, the oxygen GCIB is irradiated onto the pillar structure 49 in which the polymer layer 47 is formed on the lateral side by the plasma etching, under an atmosphere of the acetic acid gas. Accordingly, the polymer layer 47 is chemically removed through the promoted oxidation of metal existing in the polymer layer 47 by the kinetic energy of the oxygen gas clusters 37, the surrounding and sublimation of the metal oxide by the acetic acid molecules, and the decomposition of the organic substance contained in the polymer layer 47 by the kinetic energy of the oxygen gas clusters 37. As a result, since the MgO film 38 and the CoFeB films 39 and 40 are not in electrical conduction by the polymer layer 47, it is possible to prevent the normal operation of the MRAM from being hampered.

In addition, in order to prevent damage from occurring in the respective films of the pillar structure 49, like the first embodiment, the acceleration voltage of the accelerator 31 of the GCIB irradiating device 26 may be set to be equal to or lower than 10 kV to prevent the kinetic energy of the oxygen gas clusters 37 from being excessively increased.

Next, a semiconductor device production method according to a third embodiment of the present disclosure will be described. The semiconductor device production method according to the third embodiment is also performed by the semiconductor device production apparatus 10.

This embodiment is basically identical to the first embodiment in configuration and operation and is different from the first embodiment in that an ion milling as a physical etching process is performed on the stack structure 43 of the wafer W. Therefore, duplicate configurations and operations will not be explained and only different configurations and operations will be explained below.

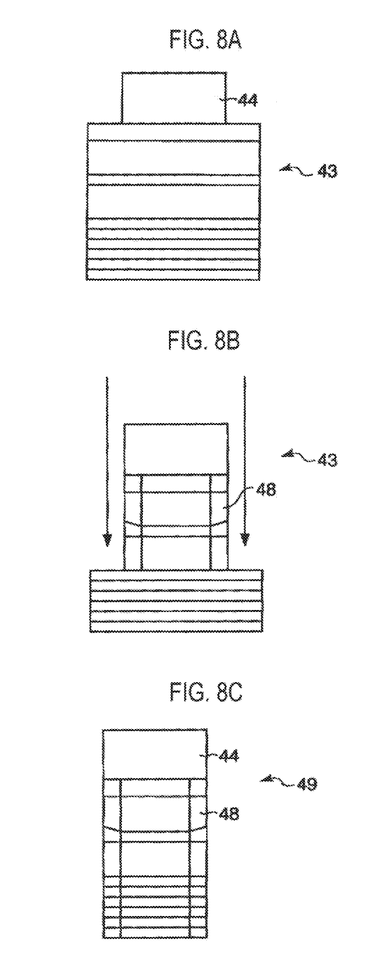

For example, in the etching module 11, as shown in FIG. 8A, the ion milling is performed on the stack structure 43 of the wafer W on which the hard mask 44 is formed. Since a sputtering of the ion milling is weak, the hard mask 44 is not cut by the ion milling. Therefore, the hard mask 44 is not reduced in size even with time.

If the size of the hard mask 44 is not reduced and the width thereof is not changed, a portion covered by the hard mask 44 in the respective films of the stack structure 43 is not cut by the etching (FIG. 8B). However, since ion straightness in the ion milling is not so high, ions are implanted into the lateral side (end portions of the respective films) of the stack structure 43 so that a damage layer 48 (including a bird's peak which is a beak-like magnetic characteristic change portion formed at both ends of the MgO film 38) composed of the ends portions of the respective films whose crystallinity is lost is formed below the hard mask 44 in the lateral side of the pillar structure 49 (FIG. 8C). Since the damage layer 48 has no crystallinity, magnetic characteristics of the respective films are changed, which hampers the normal operation of the MRAM including the MTJ element 45.

In this embodiment, the oxygen GCIB is used to remove the damage layer 48 formed on the lateral side of the pillar structure 49.

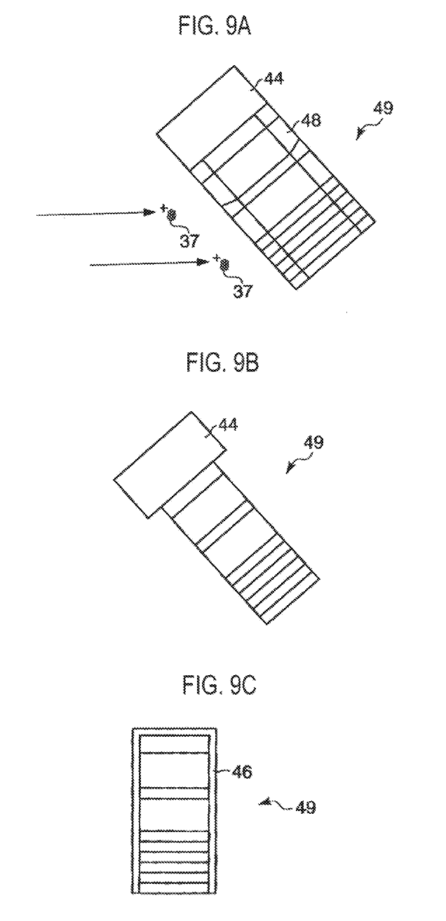

FIGS. 9A to 9C are process views illustrating the semiconductor device production method according to this embodiment.

Referring to FIGS. 9A to 9C, first, a portion not covered by the hard mask 44 in the stack structure 43 of the wafer W is cut by performing an ion milling on the stack structure 43 of the wafer W in the etching module 11, thereby obtaining the pillar structure 49 (in a first processing step).

Subsequently, the wafer W having the pillar structure 49 with its lateral side on which the damage layer 48 is formed by the ion milling is loaded into the trimming module 12. At this time, the wafer W is positioned to face the GCIB irradiating device 26 by a combination of the mounting table 23 and the arm part 25. However, as shown in FIG. 8C, since the damage layer 48 is formed below the hard mask 44, if the top portion of the pillar structure 49 directly faces the GCIB irradiating device 26, the oxygen gas clusters 37 having a very high straightness do not collide with the damage layer 48.

Therefore, in this embodiment, an amount of projection of the arm part 25 from the mounting table 23 is adjusted to tilt the wafer W with respect to the GCIB irradiating device 26 such that the lateral side of the pillar structure 49 directly faces the GCIB irradiating device 26.

Subsequently, an acetic acid gas is supplied into the processing chamber 22 of the trimming module 12. Further, an oxygen GCIB is irradiated from the GCIB irradiating device 26 toward the wafer W (FIG. 9A) (in a second processing step). Since the lateral side of the pillar structure 49 directly faces the GCIB irradiating device 26, the oxygen gas clusters 37 collide with the damage layer 48 formed on the lateral side of the pillar structure 49.

At this time, oxidation of the metal (including the noble metal) existing in the damage layer 48 is promoted by the kinetic energy of the oxygen gas clusters 37 and oxygen molecules decomposed from the oxygen gas clusters 37, thereby producing a metal oxide. The metal oxide is surrounded by a number of acetic acid molecules of the acetic acid gas and is sublimated and removed from the damage layer 48 (FIG. 9B).

Thereafter, the hard mask 44 is removed from the wafer W having the pillar structure 49 in which the damage layer 48 is removed from the lateral side, and subsequently, is moved from the trimming module 12 into the film forming module 13 via the transfer module 16. Subsequently, in the film forming module 13, a SiN film 46 is formed to cover the exposed surface of the pillar structure 49 by the plasma-based CVD process (FIG. 9C), and the method is ended.

With the semiconductor device production method of FIGS. 9A to 9C, the oxygen GCIB is irradiated onto the pillar structure 49 in which the damage layer 48 is formed on the lateral side by the ion milling, under an atmosphere of the acetic acid gas. Accordingly, the damage layer 48 whose crystallinity is lost is chemically removed through the promoted oxidation of metal existing in the damage layer 48 by the kinetic energy of the oxygen gas clusters 37 and the surrounding and sublimation of the metal oxide by the acetic acid molecules. As a result, magnetic characteristics of the respective films in the pillar structure 49 are not changed, which makes it possible to prevent the normal operation of the MRAM including the MTJ element 45 from being hampered.

In addition, in order to prevent damage from occurring in the respective films of the pillar structure 49, like the first embodiment, the acceleration voltage of the accelerator 31 of the GCIB irradiating device 26 may be set to be equal to or lower than 10 kV. Thus, it is possible to prevent the decomposed oxygen molecules from being implanted into the lateral side of the pillar structure 49 by the excessively-increased kinetic energy of the oxygen gas clusters 37.

Next, a semiconductor device production method according to a fourth embodiment of the present disclosure will be described. The semiconductor device production method according to the fourth embodiment is also performed by the semiconductor device production apparatus 10.

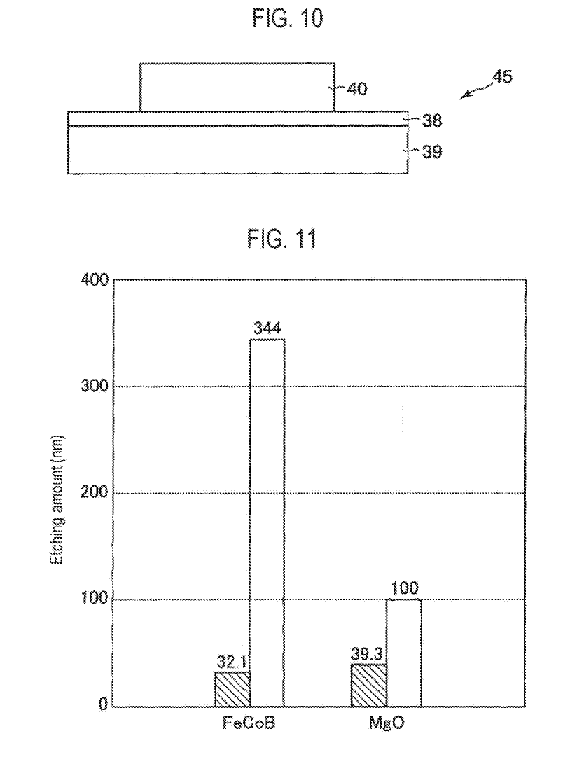

Typically, in the MTJ element 45, widths of the two CoFeB films 39 and 40 are set to be equal to each other. However, in recent years, as shown in FIG. 10, there has been proposed forming the MTJ element 45 in a stepped shape by setting the width of the lower CoFeB film 39 (hereinafter referred to as a “reference layer 39”) (the first ferromagnetic film) to be larger than the width of the upper CoFeB film 40 (hereinafter referred to as a “free layer 40”) (the second ferromagnetic film).

In the MTJ element 45, information storage is performed by controlling a magnetization state of the free layer 40. An thermal stability of the magnetization state of the free layer 40 is increased with a more uniform distribution of magnetic force lines applied to the free layer 40. Thus, the MRAM including the MTJ element 45 can be stably used as a nonvolatile memory.

In order to form the MTJ element 45 in the stepped shape in the pillar structure 49 obtained by the semiconductor device production methods according to the first to third embodiments, in general, it may be considered that a portion of the free layer 40 is covered by a hard mask and the other exposed portion of the free layer 40 is cut by the plasma etching or the ion milling. However, since it is typically difficult to secure an etching selectivity of a magnetic metal layer such as a CoFeB layer with respect to an oxide film such as an MgO film, which constitute an MTJ element, it is difficult to precisely etch the free layer 40 by a desired amount.

In this regard, prior to the present disclosure, the present inventors have irradiated an oxygen GCIB onto an MgO film and a CoFeB film in a state where an ionization voltage is set to 185V, an acceleration voltage is set to 20 kV and an amount of oxygen gas clusters 37 to be collided is set to 2×10¹⁶ ions/cm², using the GCIB irradiating device 26. As a result, the present inventors found that cut amounts (etched amounts) of the MgO film and the CoFeB film were respectively 39.3 mm and 32.1 mm, without being substantially varied, under an atmosphere where no acetic acid gas is present (see a bar graph indicated by hatching in FIG. 11), whereas cut amounts (etched amounts) of the MgO film and the CoFeB film were respectively 100 mm and 344 mm under an atmosphere where the acetic acid gas is present (a partial pressure of the acetic acid gas is 5.3×10⁻³ Pa in the atmosphere) (see a bar graph indicated by plain in FIG. 11), so that an etching selectivity of the CoFeB film with respect to the MgO film was secured by about 3.4 times.

Therefore, in this embodiment, the oxygen GCIB is used to form the MTJ element 45 in a stepped shape in the pillar structure 49 by using the etching selectivity of the CoFeB film with respect to the MgO film.

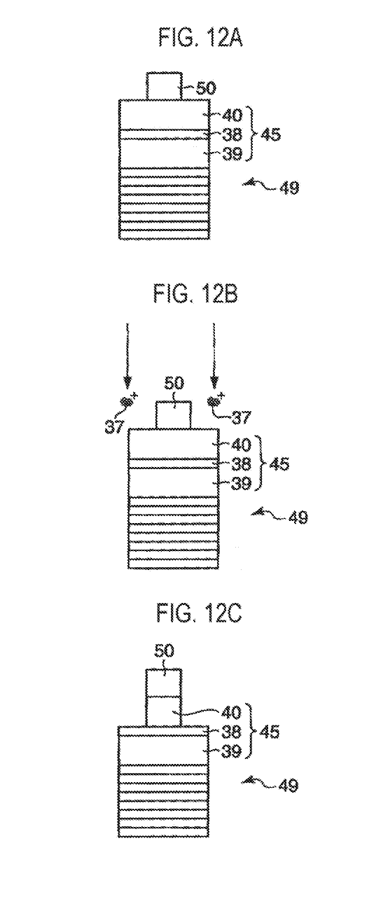

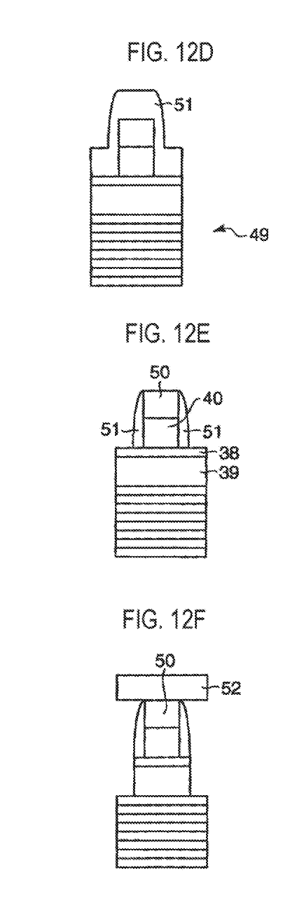

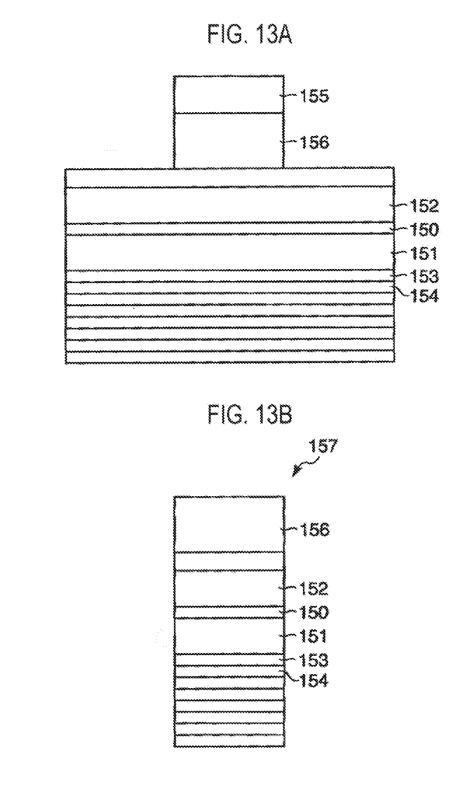

FIGS. 12A to 12F are process views illustrating the semiconductor device production method according to this embodiment.

Referring to FIGS. 12A to 12F, first, one of the semiconductor device production methods according to the first to third embodiments in the semiconductor device production apparatus 10 is performed up to the process of irradiating the oxygen GCIB onto the pillar structure 49 to obtain a pillar structure 49 (see FIG. 12A) having a lateral side inclination that is alleviated in the trimming module 12 (see FIG. 5B), or from which the polymer layer 47 or the damage layer 48 formed on the lateral side is removed (see FIGS. 7B and 9B).

Thereafter, the MTJ element 45 is exposed by removing the hard mask 44 or a film formed above the MTJ element 45 from the obtained pillar structure 49, and subsequently, a mask 50 (other mask film) for partially covering the free layer 40 of the MTJ element 45 is formed (FIG. 12A). Subsequently, an acetic acid gas is again supplied into the processing chamber 22 of the trimming module 12 and an oxygen GCIB is further irradiated from the GCIB irradiating device 26 toward the wafer W (FIG. 12B). At this time, since the etching selectivity of the CoFeB film with respect to the MgO film is about 3.4 times, the exposed free layer 40 is actively removed, whereas the MgO film 38 is not removed. Therefore, the MTJ element 45 having the stepped shape is formed in the pillar structure 49 (FIG. 12C).

Subsequently, the wafer W having the stepped pillar structure 49 is moved from the trimming module 12 into the film forming module 13 via the transfer module 16. Thereafter, in the film forming module 13, a SiN film 51 is formed to cover the exposed surface of the pillar structure 49 by the plasma-based CVD process (FIG. 12D). Further, the SiN film 51 is etched by GCIB or an anisotropic etching such as a plasma etching. The SiN film 51 is decreased in a thickness direction by the anisotropic etching. As such, if the anisotropic etching is stopped at the time of exposing the MgO film 38, the SiN film 51 remains in only lateral sides of the mask 50 and the free layer 40 (FIG. 12E). In some embodiments, the anisotropic etching may continue to be performed even if the MgO film 38 is exposed and may be stopped at the time of exposing the reference layer 39.

Subsequently, using the SiN film 51 or the mask 50 as a mask, the MgO film 38 and the reference layer 39 is etched by GCIB or the anisotropic etching such as the plasma etching. The anisotropic etching is stopped when a Ta film 41 is exposed. At this time, the Ta film 41 or the like may be etched. In this case, it is preferable to perform the plasma etching from the viewpoint of improvement of throughput. However, the performance of the plasma etching causes damages in the respective films so that a polymer is attached to lateral sides of the respective films. Thus, it is preferable to remove a place where damage occurs and the polymer by further irradiating the oxygen GCIB onto the pillar structure 49. On the other hand, in a case where the Ta film 41 or the like is not etched, it is preferable to use GCIB as the anisotropic etching.

Subsequently, an upper electrode 52 is formed on the mask 50 (FIG. 12F), and the method is ended.

With the semiconductor device production method of FIGS. 12A to 12F, the oxygen GCIB is irradiated toward the MTJ element 45 constituted by stacking the reference layer 39, the MgO film 38 and the free layer 40 in this order. Under an atmosphere of the acetic acid gas, since the etching selectivity of the CoFeB film to the MgO film in the irradiation of the oxygen GCIB is about 3.4 times, the exposed free layer 40 is actively removed, whereas the MgO film 38 is not removed. As a result, the MTJ element 45 of the stepped shape can be easily obtained (FIG. 12C).

In addition, the present inventor found that, if the oxygen GCIB is irradiated from the GCIB irradiating device 26 to the exposed MTJ element 45 in a state where the acceleration voltage is set to 10 kV, the etching selectivity of the CoFeB film to the MgO film can be secured at a level more than about 3.4 times. Therefore, in the semiconductor device production method of FIGS. 12A to 12F, when the oxygen GCIB is irradiated onto the exposed MTJ element 45, it is preferable to set the acceleration voltage to be equal to or lower than 10 kV. Thus, the MTJ element 45 having a stepped shape can be more reliably obtained.

In the semiconductor device production method of FIGS. 12A to 12F, the oxygen GCIB has been described to be irradiated onto the pillar structure 49 in which an inclination of the lateral side is alleviated under an atmosphere of the acetic acid gas, the present disclosure is not limited thereto. In some embodiments, a film above the hard mask 44 or the MTJ element 45 may be removed without alleviating the inclination of the lateral side of the pillar structure 49, and the oxygen GCIB may be irradiated onto the pillar structure 49 under an atmosphere of the acetic acid gas. If the lateral side of the stack structure 43 is inclined, the width of the reference layer 39 is larger than the width of the free layer 40. Thus, by irradiating the oxygen GCIB to actively reduce the width of the free layer 40, it is possible to reliably make the width of the reference layer 39 larger than the width of the free layer 40.

Although the present disclosure has been described by way of the above embodiments, the present disclosure is not limited thereto.

As an example, when both the plasma etching and the ion milling are used in the etching module 11, a pillar structure 49 having an inclined lateral side and a damage layer 48 formed on the lateral side or a pillar structure 49 having a polymer layer 47 and a damage layer 48 formed on its lateral side may be obtained. In this case, by irradiating an oxygen GCIB onto the pillar structure 49 under an atmosphere of the acetic acid gas, it is possible to alleviate the inclination of the lateral side and remove the damage layer 48 formed on the lateral side, or remove both the polymer layer 47 and the damage layer 48 formed on the lateral side.

Moreover, the objective of the present disclosure may be achieved by providing a memory medium that stores a program code of a software for implementing respective functions of the above embodiments to a computer, e.g., the control part 21, and by allowing a central processing unit of the control part 21 to read and execute the program code stored in the memory medium.

In such a case, the program code itself which read from the memory medium implements the respective functions of the above embodiments, and the program code and the memory medium that stores the program code constitute the present disclosure.

In addition, examples of the memory medium for providing the program code may include RAM, NV-RAM, a floppy (registered mark) disk, a hard disk an optomagnetic disk, an optical disk such as CD-ROM, CD-R, CD-RW and DVD (DVD-ROM, DVD-RAM, DVD-RW, DVD+RW), a magnetic tape, a nonvolatile memory card, and other ROMs, which are capable of storing the program code. Alternatively, the program code may be provided to the control part 21 by downloading from another computer and data base (both not shown) which are connected to an internet, a commercial network, a local area network or the like.

Further, the respective functions of the above embodiments may be implemented by executing the program code which is read by the control part 21, and by allowing an OS (operating system) running on the CPU to execute a portion or all of the actual processes based on an instruction of the program code.

Further, the respective functions of the above embodiments may be implemented by writing the program code read from the memory medium into a memory provided in a function expansion board inserted into the control part 21 or a function expansion unit connected to the control part 21, and by allowing a CPU or the like provided in the function expansion board or the function expansion unit to execute a portion or all of the actual processes based on an instruction of the program code.

The program code may be configured in a form such as an object code, a program code executed by an interpreter, a script data provided to the OS, or the like.

This application claims the benefit of Japanese Patent Application No. 2014-049305, filed on Mar. 12, 2014, in the Japan Patent Office, the disclosure of which is incorporated herein in its entirety by reference.

### EXPLANATION OF REFERENCE NUMERALS

W: wafer
10: semiconductor device production apparatus
11: etching module
12: trimming module
13: film forming module
26: GCIB irradiating module
37: oxygen gas cluster
38: MgO film
39: reference layer (CoFeB film)
40: free layer (CoFeB film)
44: hard mask
45: MTJ element

What is claimed is:

1. A method for producing a semiconductor device including at least a MTJ element and a metal layer, the MTJ element having a stack structure composed of a first ferromagnetic film, an insulating film and a second ferromagnetic film which are stacked in this order, comprising:
a first processing step of etching the stack structure by an ion milling or a plasma etching; and
a second processing step of irradiating a gas cluster ion beam (GCIB) onto the stack structure after the first processing step,
wherein the second processing step includes supplying an acetic acid gas around the stack structure and irradiating an oxygen GCIB onto the stack structure.

2. The method of claim 1, wherein the second processing step includes supplying the acetic acid gas toward the MTJ element and irradiating the oxygen GCIB onto the MTJ element.

3. The method of claim 1, wherein a mask film is formed on the stack structure, and
wherein the first processing step includes reducing the mask film by the plasma etching.

4. The method of claim 2, wherein the first processing step includes inclining a lateral side of the stack structure.

5. The method of claim 1, wherein a mask film is formed on the stack structure, and
wherein the first processing step includes suppressing reduction of the mask film by the plasma etching.

6. The method of claim 5, wherein the first processing step includes forming a polymer layer on the lateral side of the stack structure.

7. The method of claim 1, wherein a mask film is formed on the stack structure, and
wherein the first processing step includes etching the stack structure by the ion milling.

8. The method of claim 7, wherein the second processing step includes supplying an acetic acid gas toward a lateral side of the stack structure and irradiating the oxygen GCIB onto the lateral side.

9. The method of any one of claims 1 to 8, wherein, in the second processing step, an acceleration voltage to accelerate a cluster of the oxygen when the oxygen GCIB is generated is equal to or lower than 10 kV.

10. The method of any one of claims 1 to 9, further comprising: covering an exposed surface of the stack structure with a nitride film after the second processing step.

11. The method of any one of claims 1 to 10, further comprising: after the second processing step, a third processing step of exposing the MTJ element by removing the mask film formed on the stack structure, forming another mask film partially covering the second ferromagnetic film, supplying an acetic acid gas toward the stack structure, and irradiating an oxygen GCIB toward the stack structure.

12. The method of claim 11, wherein the third processing step includes forming the MTJ element in a stepped shape.

13. The method of claim 11 or 12, wherein, in the third processing step, an etching selectivity of the second ferromagnetic film to the insulating film is equal to or more than three times.

14. The method of any one of claims 11 to 13, further comprising: a fourth processing step of covering the MTJ element formed in the stepped shape with a SiN film, and removing the SiN film by an anisotropic etching.

15. The method of claim 14, further comprising: a fifth processing step of removing the insulating film and the first ferromagnetic film by the anisotropic etching using the SiN film remaining in the fourth processing step as a mask.

16. An apparatus for producing a semiconductor device having a stack structure including at least a MTJ element and a metal layer, comprising:
a first processing unit configured to etch the stack structure by an ion milling or a plasma etching; and
a second processing unit configured to irradiate a gas cluster ion beam (GCIB) onto the etched stack structure,
wherein the second processing unit supplies an acetic acid gas around the stack structure and irradiates an oxygen GCIB onto the stack structure.

17. The apparatus of claim 16, wherein an exposed surface is formed in the stack structure by the irradiation of the oxygen GCIB,
further comprising: a film forming unit configured to cover the exposed surface of the stack structure with a nitride film.
